(19) United States
(12) Patent Application Publication
(10) Pub. No.: US 2009/0011370 A1
(43) Pub. Date: Jan. 8, 2009

(54) PATTERN FORMING METHOD USING TWO LAYERS OF RESIST PATTERNS STACKED ONE ON TOP OF THE OTHER

(76) Inventors: Hiroko Nakamura, Yokohama-shi (JP); Koji Hashimoto, Yokohama-shi (JP); Soichi Inoue, Yokohama-shi (JP); Toshiya Kotani, Machida-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/136,368

(22) Filed: Jun. 10, 2008

(30) Foreign Application Priority Data
Jun. 11, 2007 (JP) 2007-154483
Jun. 15, 2007 (JP) 2007-158904

(51) Int. Cl. G03F 7/22

(52) U.S. Cl. 430/322

(57) ABSTRACT

A pattern forming method using two layers of resist pattern stacked one on the other has been disclosed. First, a first resist pattern is formed on a to-be-processed film. The first resist pattern is slimmed. On the slimmed first resist pattern and to-be-processed film, a second resist pattern is formed. With the first and second resist patterns as a mask, the film is processed.

### CROSS-REFERENCE TO RELATED APPLICATIONS

This application is based upon and claims the benefit of priority from prior Japanese Patent Applications No. 2007-154483, filed Jun. 11, 2007; and No. 2007-158904, filed Jun. 15, 2007, the entire contents of both of which are incorporated herein by reference.

### BACKGROUND OF THE INVENTION

1. Field of the Invention

This invention relates to the lithographic technique for forming a pattern of a semiconductor device, and more particularly to a pattern forming method using two layers of resist patterns stacked one on the other.

2. Description of the Related Art

Semiconductor devices have been miniaturized by increasing the numerical apertures (NA) of an exposure device or by decreasing the wavelength of exposure light. However, the miniaturization of the pattern dimensions of semiconductor devices takes place so remarkably that the above technical measures are not sufficient in forming desirable patterns with sufficient margins. To solve this problem, sliming is executed after the patterning by lithography. An asher (ashing device) is used for the slimming.

In slimming, not only the desired pattern but also its surrounding patterns become thinner. Therefore, as for patterns other than micropatterns, a pattern with an increased width is formed beforehand by lithography, taking the amount of slimming into account.

However, as the amount of slimming is larger, the widths of the patterns excluding the micropatterns have to be made greater, narrowing the space width between adjacent patterns, which then makes it impossible to lithographically achieve the dimensions of the patterns excluding the micropatterns.

Moreover, when the width is made greater beforehand, taking the amount of slimming into account, this might make it impossible to obtain a desired margin.

In such a case, a method called a hard mask process is used. Specifically, first, a line pattern corresponding to a micropattern is formed using a first resist. After slimming is done by ashing, the line pattern is transferred to a hard mask. Thereafter, the first resist pattern is peeled. Using a second resist, a narrow space pattern is formed. With the hard mask and second resist pattern as a mask, the to-be-processed film is etched. Finally, the second resist pattern and hard mask are removed, thereby obtaining a desired pattern.

Another description will now be given among technologies for executing slimming of resist by means of an asher (ashing device) after the patterning by lithography and for forming a desired pattern with a sufficient margin.

To form a fine pattern which cannot be formed by single exposure, first, a 1:3 line-and-space (L&S) resist pattern whose period is double the desired period is formed and then transferred to a hard mask.

Thereafter, resist is applied again. Then, the 1:3 L&S pattern shifted by a desired period is exposed, and developed, thereby finally forming an L&S pattern with a desired period (e.g., refer to S. Lee, et al., “Double exposure technology using silicon containing materials,” Proc. of SPIE, Vol. 6153 (2006)).

It is no problem if the 1:3 L&S resist pattern can be formed with sufficient margin. The process window of an L&S pattern whose line width is greater than that of the 1:3 L&S resist pattern can be made wider than that of the 1:3 L&S resist pattern in the lithographic process. Therefore, first, the line width of an L&S pattern is often made greater than that of the 1:3 L&S pattern. Thereafter, ashing is performed, thereby forming a 1:3 L&S pattern, which is then transferred to the hard mask.

However, in every pattern mentioned above, since the slimmed resist pattern is transferred to the hard mask once, the number of processes increases, resulting in a rise in the cost.

Another approach to form a desired pattern with a sufficient margin is double exposure technology which exposes one layer of resist to light twice by use of different masks.

The resist pattern serving as an etching mask may include various patterns, depending on the layer. Therefore, in narrow-margin lithography, it is difficult to form all patters with sufficient exposure margins by single illumination. Therefore, restrictions are placed on the design patterns so as to use only patterns which can be formed by the illumination or a pattern is divided into two double exposure.

First, a case where restrictions are put on designing so as to use only patterns which can be formed by the illumination will be explained. Under the conditions where illumination conditions are fixed so as to be advantageous to the formation of a dense pattern, when the depth of focuses (DOFs) are observed, while the line width and space width are being changed, the depth of focus decreases in the case of isolated lines and isolated spaces. At the time of manufacturing devices, patterns with various duty ratios have to be formed at the same time. However, since the depth of focus of a microscopic isolated space cannot be secured, restrictions are imposed in the design stage so as not to form microscopic isolated spaces.

In the following case, a pattern is divided into two for double exposure. For example, in the M1 layer of a NAND flash memory, since one type of microscopic periodic L&S pattern is arranged in the cell part, exposure is made with an L&S mask using dipolar illumination according to the pitch. However, the peripheral part including various types of L&S patterns cannot be formed by the dipolar illumination and therefore exposure is made by orbicular zone illumination different from dipolar illumination.

The process flow at this time is as follows. After a resist is applied and soft baking is done, an L&S pattern is produced by dipolar illumination. Next, the peripheral circuit part is exposed by orbicular zone illumination. Moreover, post-exposure baking (PEB) is performed. Finally, the pattern is developed, thereby obtaining a resist pattern of the M1 layer.

However, the patterns exposed at different times cannot be mixed. The reason is that, if they are mixed, the aerial images are added in the resist, preventing the desired performance from being obtained. Therefore, the places where the patterns are formed are divided. However, just dividing the places raises the following problem.

In each exposure, a flare accounting for several percent of the dose is superimposed (a part not to be exposed has been exposed by the background). If one exposure is made, there is no problem. However, when the same place is exposed twice, the flare doubles. When there is the flare, the contrast decreases, degrading the aerial image. This appears prominently in narrow-margin lithography, which becomes a big problem.

As described above, when one layer of resist is exposed twice, a flare caused by one exposure is superimposed or an aerial image is added in the resist, which prevents an exposure margin to be obtained by single exposure from being obtained.

To avoid the problems, the following measures have been taken.

For example, to avoid the influence of a flare, a shading film is provided on a reticle to shield the pattern from a flare. When the cell part and peripheral circuit part are exposed at different times, reticles separating the individual patterns are used. In the case of a reticle used in exposing the L&S pattern in the cell part, the place corresponding to the peripheral circuit part is covered with a shading film. In the case of a reticle used in exposing the peripheral circuit part, a shading film is formed in the place corresponding to the L&S pattern of the cell part. Furthermore, since light goes around at the boundary between them, a pattern-less region with a width of 20 μm to 40 μm on a reticle (a width of 5 μm to 10 μm on a wafer) is provided. Consequently, the chip area increases.

In this case, the cell part and peripheral circuit part cannot be connected in the M1 layer. When the wiring lines are drawn from the cell part to the peripheral circuit part, the wiring lines are drawn down from each of the cell part and peripheral circuit part in the M1 layer to a lower M0 layer through contact holes. The cell part and peripheral circuit part are connected via the wiring lines in the M0 layer. Accordingly, the following problems arise: the resistance value of the wiring line increases, the reliability decreases, or the chip area increases.

Similarly, in double dipole lithography (DDL) where exposure is made twice, the part corresponding to the wiring lines perpendicular to the wiring lines to be exposed is covered with a shading film on the reticle (e.g., refer to S. D. Hsu, et al., “Diope Decomposition Mask-Design for Full Chip Implementation,” Proc. SPIE vol. 4691, 476 (2002)). The DDL is a method of dividing the wiring lines into the vertical wiring lines and horizontal wiring lines of a periodic L&S pattern, only the vertical wiring lines are first exposed by dipolar illumination, and then only the horizontal wiring lines are exposed by dipolar illumination with the position of the aperture being rotate by 90 degrees, thereby forming microscopic wiring lines.

In this case, too, the aerial images formed by two exposures are added as described above. Accordingly, to increase the contrast, for example, in the case of the formation of vertical lines, light has to be allowed to arrive only at the time of exposure for the vertical line direction, and light has to be prevented from arriving at the time of exposure for the horizontal line direction. Moreover, when exposure is made in the horizontal line direction, the part corresponding to the vertical lines is covered with a shading film on the reticle. This is referred to as shielding in the above paper.

However, since the shading film is larger than the original pattern, a region capable of arranging the shading film is necessary. This puts restrictions on the pattern, leading to an increase in the chip area. In the region which connects vertical lines and horizontal lines, since the shading film is larger than the original pattern, the junction parts of the wiring lines are connected not at a pattern clearly exposed by dipolar illumination, but at a pattern left by the shading film.

Furthermore, it is not easy to lay a vertical pattern and a horizontal pattern one on the other. Thus, increasing the overlay accuracy is a trial and error process because the junction part varies with the pattern size. Accordingly, a lot of labor is needed and a process margin is small, which decreases the reliability.

As described above, when different patterns are formed in the same layer in narrow margin lithography, restrictions have to be placed on the design patterns, for example, so as not to form a pattern whose depth of focus is small. Moreover, when double exposure is made, the chip area becomes larger to allow for the boundary between separated patterns, or the trouble has to be taken to make contact holes and connect wiring lines in a different layer. Furthermore, in a DDL process, vertical patterns and horizontal patterns are connected via a margin-less pattern, which decreases the reliability of wiring.

### BRIEF SUMMARY OF THE INVENTION

According to an aspect of the invention, there is provided a pattern forming method comprising: forming a first resist pattern on a to-be-processed film; slimming the first resist pattern; forming a second resist pattern on at least either the slimmed first resist pattern or the to-be-processed film; and processing the to-be-processed film, with the first and second resist patterns as a mask.

According to another aspect of the invention, there is provided a pattern forming method comprising: forming a first bottom anti-reflective coating on a to-be-processed film; forming a first resist pattern on the first bottom anti-reflective coating; slimming the first resist pattern; processing the first bottom anti-reflective coating with the slimmed first resist pattern as a mask; forming a second bottom anti-reflective coating on the first resist pattern and the to-be-processed film, after processing the first bottom anti-reflective coating; forming a second resist pattern on the second bottom anti-reflective coating; processing the second bottom anti-reflective coating with the second resist pattern as a mask; and processing the process to be processed, with the first resist pattern or the first bottom anti-reflective coating, and the second resist pattern or the processed second bottom anti-reflective coating as a mask.

According to still another aspect of the invention, there is provided a pattern forming method comprising: forming a bottom anti-reflective coating on a to-be-processed film; forming a first resist pattern on the bottom anti-reflective coating; slimming the first resist pattern; forming a second resist pattern on at least either the bottom anti-reflective coating or the slimmed first resist pattern; processing the bottom anti-reflective coating, with the first and second resist patterns as a mask; and processing the to-be-processed film, with the first resist pattern, second resist pattern, or the processed bottom anti-reflective coating as a mask.

### BRIEF DESCRIPTION OF THE SEVERAL VIEWS OF THE DRAWING

FIG. 1 is a plan view of a line pattern and a contact fringe finally formed in a pattern forming method according to an embodiment of the invention;

FIG. 2 is a plan view of a pattern formed before slimming in a case where the pattern of FIG. 1 is formed by slimming;

FIGS. 3A to 3F are plan views to help explain a pattern forming method using a hard mask;

FIG. 4 is a flowchart to help explain the pattern forming method shown in FIGS. 3A to 3F;

FIGS. 5A to 5D are plan views to help explain a pattern forming method according to a first embodiment of the invention;

FIG. 6 is a flowchart to help explain the pattern forming method according to the first embodiment;

FIGS. 7A to 7G are plan views to help explain the pattern forming method using a hard mask;

FIG. 8 is a flowchart to help explain the pattern forming method shown in FIGS. 7A to 7G;

FIGS. 9A to 9D are plan views to help explain a pattern forming method according to a second embodiment of the invention;

FIG. 10 is a flowchart to help explain the pattern forming method according to the second embodiment;

FIGS. 11A to 11F are sectional views to help explain a pattern forming method according to a third embodiment of the invention;

FIG. 12 is a flowchart to help explain the pattern forming method according to the third embodiment;

FIG. 13 is a flowchart to help explain the pattern forming method using a hard mask;

FIGS. 14A and 14B are sectional views to help explain a pattern forming method according to a fourth embodiment of the invention;

FIG. 15 is a flowchart to help explain the pattern forming method according to the fourth embodiment;

FIG. 16 is a distribution chart showing the depth of focus (DOF) obtained in forming L&S patterns with different duty ratio by orbicular zone illumination;

FIG. 17 is a flowchart to help explain the pattern forming method according to the fifth embodiment;

FIG. 18 is a plan view of the shape of an aperture of orbicular zone illumination;

FIG. 19 is a plan view of the shape of an aperture of normal illumination with small σ;

FIG. 20 is a flowchart to help explain the process of forming the cell part and peripheral circuit part of a NAND flash memory in such a manner that the two parts are separated from each other;

FIG. 21 is a plan view of the shape of apertures of dipolar illumination;

FIG. 22A is a plan view of a reticle used in exposing the cell part;

FIG. 22B is a plan view of a reticle used in exposing the peripheral circuit part;

FIG. 23 is a plan view of a design pattern of the wiring lines to connect the cell part to the peripheral circuit part;

FIG. 24 is a plan view of a design pattern of a drawing part which connects the cell part and peripheral circuit part in a sixth embodiment of the invention;

FIG. 25 is a flowchart to help explain the pattern forming method according to the sixth embodiment;

FIG. 26 is a diagram showing the relationship between the position of diffracted light from a periodic L&S pattern and the pupil of the projector lens at the time of normal illumination, while changing the pattern period p and NA;

FIG. 27 is a plan view to help explain oblique incidence illumination;

FIG. 28 is a diagram to help explain the way diffracted light enters the projector lens at the time of oblique incidence illumination;

FIG. 29 is a plan view to help explain dipolar illumination;

FIGS. 30A to 30C are plan views to help explain variations of illuminations which can be used when the dimensions of an L&S pattern become larger;

FIG. 31 is a plan view to help explain normal illumination with small a used in forming an isolated pattern;

FIG. 32 is a plan view showing a modification of quadrupole illumination;

FIG. 33 is a flowchart to help explain a DDL process flow;

FIGS. 34A and 34B are plan views of a reticle and illumination used when the vertical and horizontal liens are divided and then connected in DDL;

FIG. 35 is a flowchart to help explain the pattern forming method according to the seventh embodiment;

FIGS. 36A and 36B are plan views of a reticle pattern and illumination and a pattern formed on a wafer used in the seventh embodiment; and

FIG. 37 is a plan view of a contact hole pattern with a period of p in both the vertical and horizontal directions.

### DETAILED DESCRIPTION OF THE INVENTION

### First Embodiment

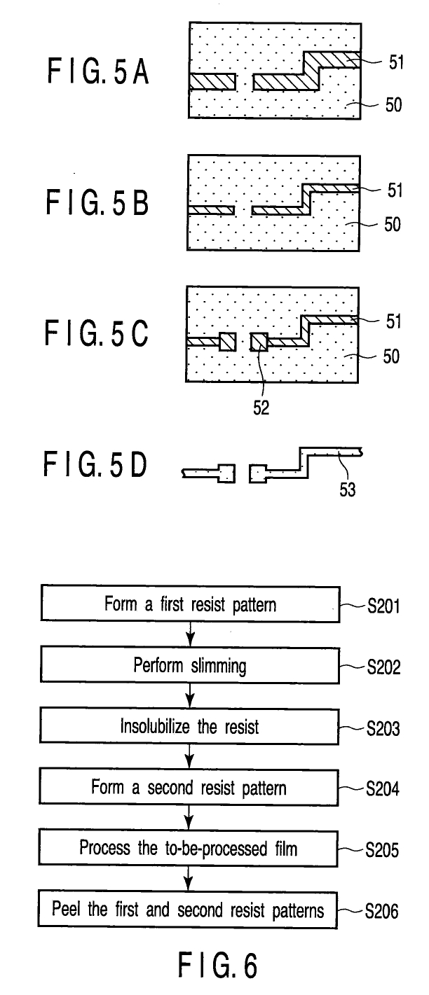

A pattern forming method according to a first embodiment of the invention will be explained using FIGS. 5A to 5D and FIG. 6.

In the pattern forming method of the first embodiment, a description will be given of an example of reducing the number of processes and the cost by laying two layers of resist pattern one on the other in place of a hard mask.

In addition, an explanation will be given taking as an example a case where a line pattern including a line corresponding to a gate in a gate layer and a contact fringe are formed.

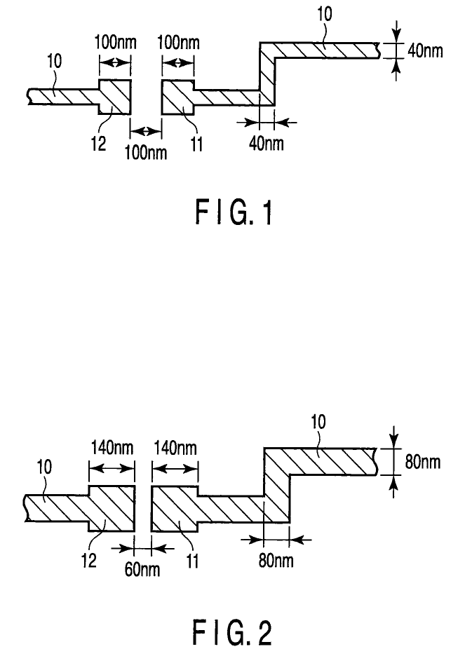

FIG. 1 shows the shape and size of a desired pattern finally to be formed. The pattern is a poly-Si (polysilicon) wiring pattern which is such that 100-nm-square contract fringes 11, 12 are formed on a 40-nm-wide line pattern 10. The spacing between the two contract fringes 11 and 12 is 100 nm.

With the pattern shape as shown in FIG. 1, it is difficult to form an isolated line pattern 10 with a line width of 40 nm. A first reason is that a reticle cannot be produced with high accuracy. A second reason is that, when a pattern is formed using a positive-tone resist, an increased amount of exposure dose makes the line thinner, but cannot obtain a wider margin. That is, sufficient amount of neither a focus margin nor a dose margin can be obtained. Moreover, the top of the pattern gets rounded or the film thickness decreased, which makes a variation in the critical dimensions larger in etching process.

To avoid the above problems, after a line 10 with a width of 80 nm is formed as shown in FIG. 2, the resist line is made thinner by ashing so that the line width becomes 40 nm. The amount of slimming is 20 nm on one side (40 nm in total). Since the desired exposure margin cannot be obtained in the line pattern 10 by lithographic patterning, the line pattern is a micropattern which needs slimming.

On the other hand, the contact fringes 11, 12 have to be formed into 140-nm squares at the time of patterning, taking a decrease in the 40-nm pattern width into account. In this case, the space between the contact fringes 11 and 12 becomes 60 nm. However, it is difficult to form a narrow space of 60 nm in a lithographic process. That is, the contact fringes 11, 12 are patterns which cannot be formed by slimming together with the line pattern 10.

Accordingly, using this method, it is impossible to form a 40-nm-wide line and a 100-nm-wide space at the same time. On the other hand, the contact fringe pattern requires a width of 100 nm to allow a wiring line to go down from the upper layer through a contact hole and therefore cannot be made smaller.

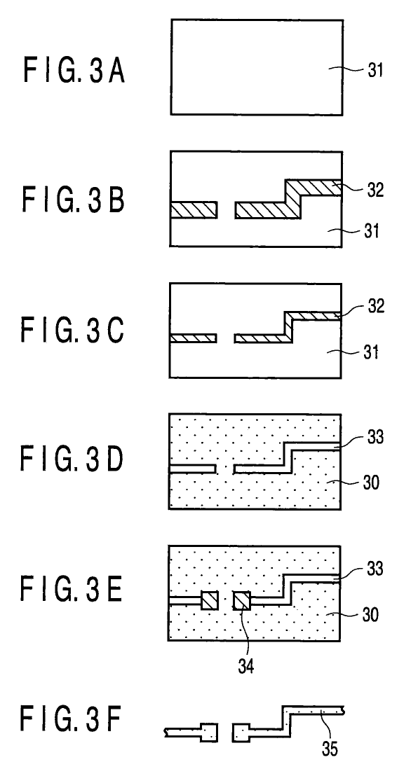

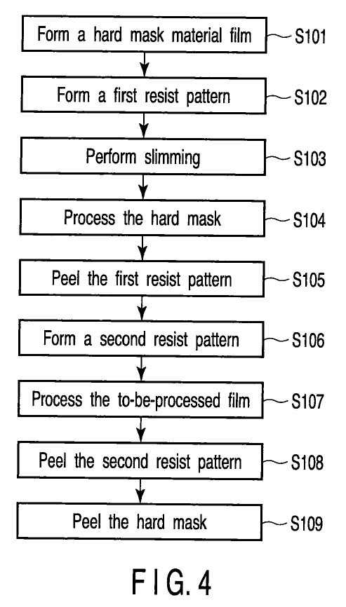

Therefore, as described below, this problem has been avoided using a hard mask. This method will be explained using the plan views of FIGS. 3A to 3F and the flowchart of FIG. 4.

First, as shown in FIG. 3A, a hard mask material 31 made of SiN is formed on a to-be-processed film (poly-Si film) 30 (not shown) (step S101 in FIG. 4). As shown in FIG. 3B, a first resist pattern 32 composed of an 80-nm-wide line is formed on the hard mask material 31 by exposure with conventional illumination with NA=0.915 and σ=0.3 (step S102). Hereinafter, the formation of a resist pattern means a process including the application of resist, soft baking, exposure, post exposure baking, and development.

Next, as shown in FIG. 3C, slimming is performed by an asher so as to make the first resist pattern 32 to a gate pattern (step S103).

Next, with the slimmed first resist pattern 32 as a mask, the hard mask material 31 is processed (step S104) and then the first resist pattern 32 is peeled, thereby forming a gate pattern composed of a hard mask 33 as shown in FIG. 3D (step S105).

Thereafter, as shown in FIG. 3E, a second resist pattern 34 is formed as a contact fringe so as to cover one end of the hard mask 33 and its surrounding poly-Si film 30 (step S106). The illumination condition for exposure at this time is orbicular zone illumination with NA=0.915, σ=0.9, and ε=⅔ because the surrounding pattern is also present. One side of a contact fringe formed by the second resist pattern 34 is 100 nm in length. The distance between two contact fringes is 100 nm.

Thereafter, with the second resist pattern 34 and hard mask 33 as a mask, the poly-Si film 30 is etched (step S107), the second resist pattern 34 is peeled (step 108), and the hard mask 33 is peeled (step 109), thereby forming a desired pattern 35 made by poly-Si film (a to-be-processed film) as shown in FIG. 3F.

In the processes shown in FIGS. 3A to 3F and FIG. 4, use of the hard mask leads to an increased number of processes and the higher cost.

To overcome this shortcoming, the first embodiment uses a method of laying two layers of resist one on the other instead of using a hard mask. The plan views in FIGS. 5A to 5D and the flowchart in FIG. 6 help explain the processes.

First, as shown in FIG. 5A, a first resist pattern 51 is formed on a to-be-processed film (a poly-Si film) 50 (step S201 of FIG. 6). Thereafter, as shown in FIG. 5B, the resist pattern is slimming by an asher (step 202), thereby forming a gate pattern with a width of 40 nm.

Next, the first resist pattern 51 is insolubilized so that the first resist pattern 51 may not dissolve in patterning a second resist pattern 52 in a subsequent process (step S203).

The insolubilizing method may be achieved by curing with UV light, DUV light, or electron beam irradiation, or by ion implantation (ion beam irradiation), or baking. Moreover, a thin film for insolubilizing may be formed between the first resist pattern 51 and second resist pattern 52, for example, on the top surface and side surface of the first resist pattern 51, thereby preventing the two patterns from mixing with each other.

The processing for insolubilizing the first resist pattern is executed to prevent the first resist pattern from dissolving in the solvent for the second resist pattern, to prevent the first resist pattern from mixing with the second resist, or to prevent the first resist pattern from dissolving during the development of the second resist pattern. Unless these problems occur, step S203 can be skipped.

Thereafter, as shown in FIG. 5C, a contact fringe pattern is formed with a second resist pattern 52 so as to cover one end of the first resist pattern 51 and its surrounding poly-Si film 50 (step S204).

Then, with the first resist pattern 51 and second resist pattern 52 as an etching mask, the poly-Si film (the to-be-processed film) 50 is etched (step S205). Finally, the first resist pattern 51 and second resist pattern 52 are peeled (step S206).

By doing this, a fringed gate pattern 53 composed of a poly-Si film can be formed as shown in FIG. 5D.

When a film for insolubilizing which is nonselective is formed between the first resist pattern 51 and second resist pattern 52, the process of etching the film for insolubilizing is added before the poly-Si film 50 is etched. In a case where the film for insolubilizing is formed only on the top surface and side surface of the resist pattern, when a film for insolubilizing is formed between the first resist pattern 51 and second resist pattern 52, the etching process need not be added. Moreover, in the peeling process, if a material of the film for insolubilizing can be peeled together with the resist, it is peeled in step S206. In the case of a material of the film for insolubilizing that cannot be peeled, the process of peeling the film for insolubilizing is further needed in step S206.

In the first embodiment, use of a resist pattern in place of a hard mask eliminates the hard mask forming, etching, and peeling processes and the first resist pattern peeling process although a resist insolubilizing process is added, which enables the number of processes to be decreased and the cost to be reduced. On the other hand, the contact fringes and gate patterns can be formed with the desired critical dimensions, which means that a pattern equivalent to the one obtained by using a hard mask can be formed.

As described above, in the first embodiment, when a micropattern formed by sliming the resist exists together with a narrow-space pattern or the like which cannot be formed with sliming process, two layers of resist pattern stacked one on the other are used in place of a hard mask.

First, after a first resist pattern is formed, slimming is done, thereby forming microscopic lines. Next, the first resist pattern is insolubilized and a second resist pattern including a narrow-space pattern is formed. Thereafter, with the first and second resist patterns as a mask, the to-be-processed film is etched, producing a desired pattern.

That is, the first and second resist patterns are patterned independently. Therefore, in the same layer, a microscopic-line pattern where the necessary margin cannot be obtained unless it is formed by slimming can be mixed with a narrow-space pattern where the necessary margin cannot be obtained if slimming is done, with sufficient margins.

Furthermore, although a microscopic resist pattern was formed and then transferred onto a hard mask in the conventional art, the pattern forming method of the first embodiment needs no hard mask and therefore the number of processes can be decreased and the cost be reduced.

### Second Embodiment

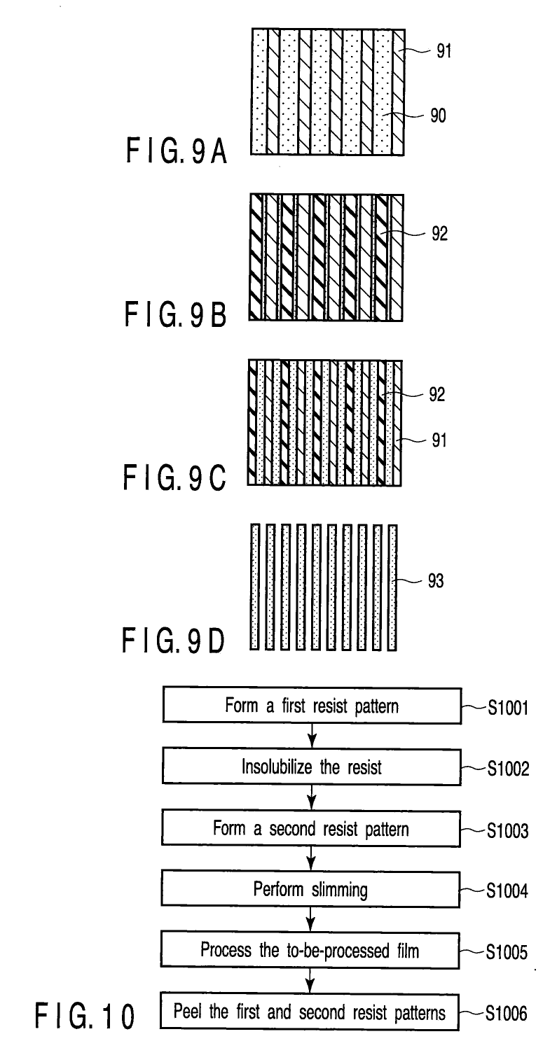

A pattern forming method according to a second embodiment of the invention will be explained using FIGS. 9A to 9D and FIG. 10.

A method of using a resist pattern in place of a hard mask is not limited to the case explained in the first embodiment and may be applied to other patterns. In the pattern forming method of the second embodiment, for example, a pattern which cannot be formed by single exposure is formed by forming a double period pattern twice, shifting a first pattern by the period, and by stacking the patterns one on the other.

Specifically, to form a fine-pitch L&S pattern which cannot be formed by single exposure, a 1:3 L&S resist pattern whose period is double the desired period is formed. Thereafter, this pattern is shifted by the desired period and a 1:3 L&S resist pattern is formed, thereby finally forming a desired period pattern.

As compared with a case where a 1:3 L&S resist pattern is formed in the first place, an L&S pattern whose line width is greater than that of the 1:3 L&S resist pattern has a wide process window in the lithographic process. Accordingly, after the line width of an L&S pattern is made greater than that of a 1:3 L&S resist pattern, the L&S pattern is subjected to ashing, thereby forming a 1:3 L&S resist pattern.

Specifically, an explanation will be given using a case where, for example, a 32-nm 1:1 L&S pattern is formed. A first resist pattern is a 128-nm-pitch L&S pattern. The following is a description of the result of exposure latitudes, while changing the line width, when the illumination conditions are quadrupolar illumination with NA=1.0, an open angle of 35 degrees, an inner a of 0.68, an outer a of 0.85, and azimuthal polarized illumination.

Since a focus depth of 300 nm or more can be secured, the following is a discussion using the exposure latitudes. When a 1:3 L&S resist pattern is formed in the first place, if the dimensional tolerance is 10% of the desired critical dimension, that is, 3.2 nm, the exposure latitude is 3.8%. However, as the line width is increased, the exposure latitude increases. When a 1:1 L&S resist pattern is formed, the exposure latitude is 7.1%. Therefore, to widen the process margin in the lithographic stage, an L&S pattern whose line width is greater than that of the 1:3 L&S resist pattern is formed and then the pattern is slimmed, thereby forming a 1:3 L&S pattern.

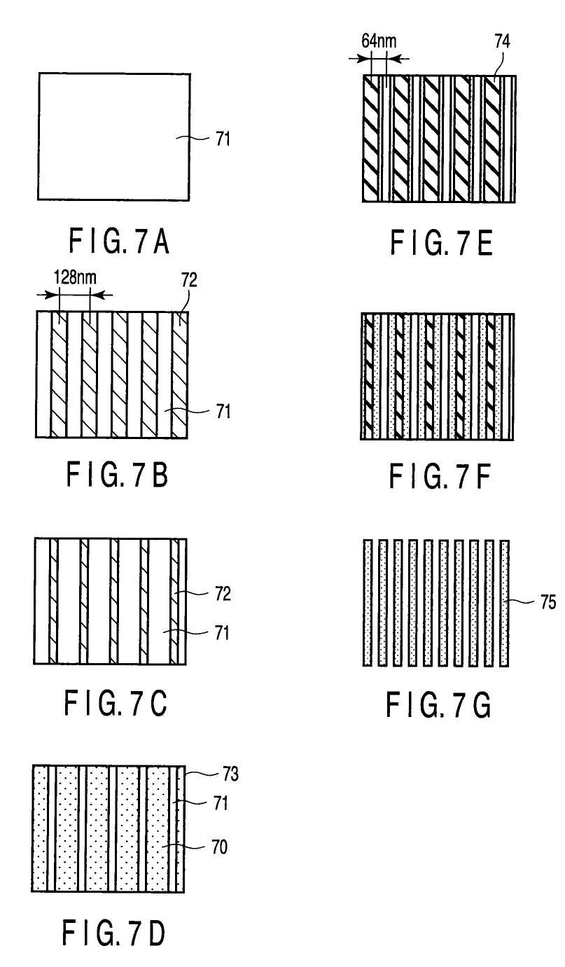

FIGS. 7A to 7G show a process flow using a hard mask in forming the aforementioned fine-pitch L&S pattern by way of comparison. The process flow is basically the same as that of the example of forming the gate and contact fringe explained using FIGS. 3A to 3F and FIG. 4 in the first embodiment.

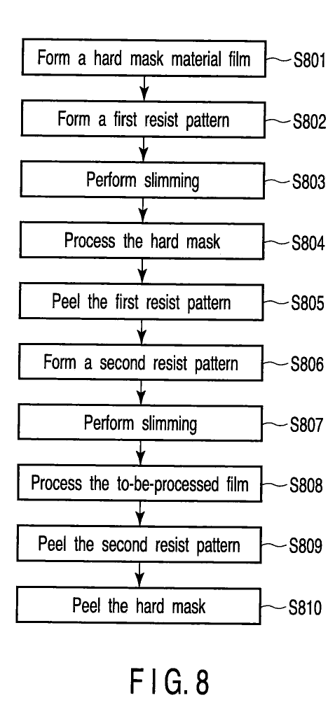

An explanation will be given using the flowchart of FIG. 8. First, in step S801, a film of a hard mask material 71 is formed (FIG. 7A). In step S802, a first resist pattern 72 is formed (FIG. 7B). In step S803, the first resist pattern is slimmed (FIG. 7C). In step S804, the hard mask material 71 is processed. In step S805, the first resist pattern 72 is peeled (FIG. 7D). In step S806, a second resist pattern 74 is formed (FIG. 7E). In step S807, the second resist pattern 74 is slimmed (FIG. 7F). In step S808, with the second resist pattern 74 and hard mask 73 as a mask, a to-be-processed film 70 is etched. Then, in step S809, the second resist pattern 74 is peeled. In step S810, the hard mask 73 is peeled, thereby producing a desired pattern 75 of the to-be-processed film (FIG. 7G).

The second embodiment differs from the case where the gate and contact fringe have been formed as explained in FIGS. 3A to 3F and FIG. 4 in that the second resist pattern 74 is a pattern obtained by shifting the first resist pattern 72 (L&S pattern) sideway by 64 nm and that the second resist pattern is formed as a line greater than 32 nm in width and then the line is slimmed by ashing, thereby forming a 32-nm-wide line.

A process flow according to the second embodiment using a resist pattern in place of a hard mask in forming the pattern will be explained using the plan views of FIGS. 9A to 9D and the flowchart of FIG. 10.

In the second embodiment, lines greater than 32 nm in width are formed in both a first resist pattern and a second resist pattern in the first place. Since the second resist pattern has to be formed in a space part of the first resist pattern, the line width of a first resist pattern 91 formed on a to-be-processed film 90 is set to 55 nm (step S1001 of FIG. 10).

When the critical dimensions of the first resist pattern 91 change as a result of a subsequent insolubilizing process and the patterning of the second resist pattern, patterning is done in step S1001, taking into account a variation in the critical dimensions of the first resist pattern 91.

Then, the first resist pattern 91 is insolubilized (step S1002). As in the first embodiment, the insolubilizing process does not have to be carried out, if the first resist pattern is insoluble in the solvent for the second resist pattern and does not mix with the second resist during the formation of the second resist pattern, or does not dissolve during the development of the second resist pattern. Next, as shown in FIG. 9B, a second resist pattern 92 is formed (step S1003). Thereafter, as shown in FIG. 9C, the first resist pattern 91 and second resist pattern 92 are slimmed at the same time by ashing (step S1004).

Next, with the first resist pattern 91 and second resist pattern 92 as a mask, the to-be-processed film 90 is etched (step S1005). Finally, the first resist pattern 91 and second resist pattern 92 are peeled (step S1006), thereby forming a desired L&S pattern of the to-be-processed film as shown in FIG. 9D.

If a hard mask is used to form a fine-pitch L&S pattern as described above, the number of processes is large and therefore the cost is high. However, use of resist in place of a hard mask as in the second embodiment makes it possible to eliminate not only the processes of forming a film of a hard mask, and processing and peeling the film, and the process of peeling the first resist pattern but also one of the slimming processes by ashing, although the resist insolubilizing process is added. Such a reduction in the number of processes enables cost reduction.

The process flow of the second embodiment using resist in place of a hard mask may be carried out in the same manner as shown in FIG. 6 of the first embodiment where the gate and contact fringe are formed. Specifically, the first resist pattern 91 may be slimmed between step S1001 and S1002, the second resist pattern 92 is formed to the desired dimensions in the first place, thereby eliminating step S1004.

In this case, although the process window in the lithographic process of the first resist pattern 91 (L&S pattern) can be made wider than that in FIGS. 9A to 9D, the process window in the lithographic process of the second resist pattern 92 (L&S pattern) gets narrower. The number of slimming (ashing) processes is the same as in the second embodiment. However, in this case, too, the number of processes and the cost can be reduced as compared with the conventional equivalent.

### Third Embodiment

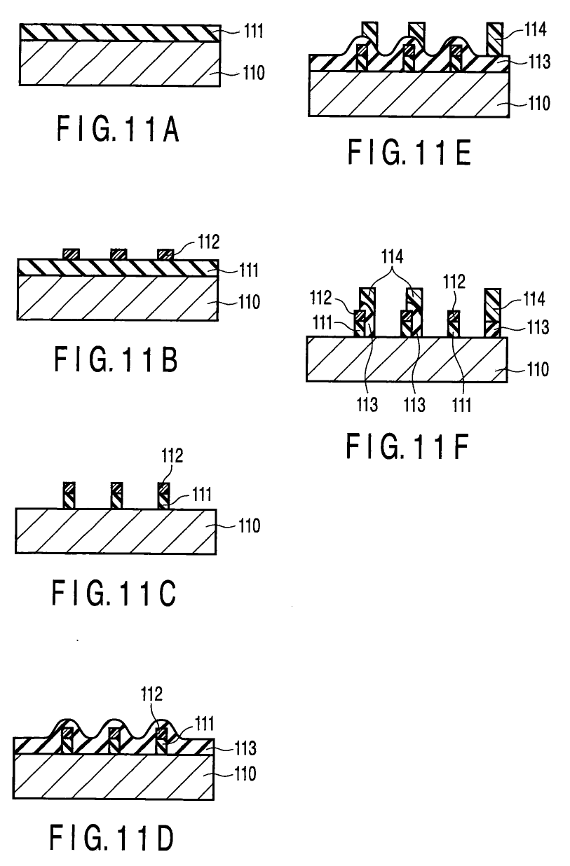

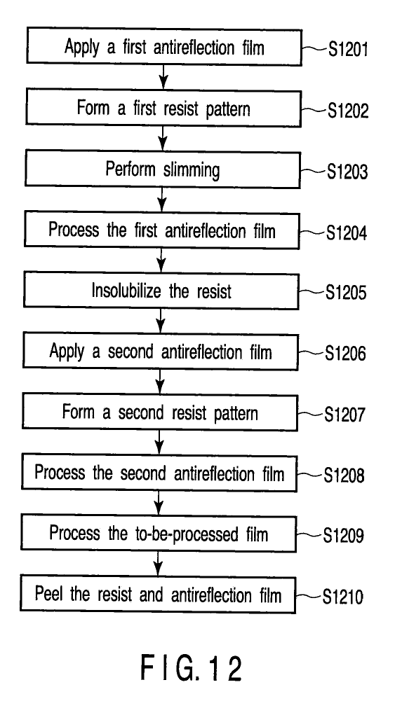

A pattern forming method according to a third embodiment of the invention will be explained using FIGS. 11A to 11F and FIG. 12.

In the pattern forming method of the third embodiment, a description will be given of the case where a Bottom Anti-Reflective Coating (BARC) is formed under a resist pattern. The third embodiment corresponds to the case where a BARC is formed in the first embodiment, in which two layers of resist patterns are formed in place of a hard mask for the purpose of reducing the number of steps and the cost.

FIGS. 11A to 11F are sectional views to help explain the processes of the pattern forming method of the third embodiment. FIG. 12 is a flowchart to help explain the pattern forming method.

First, as shown in FIG. 11A, a bottom (first) antireflection film 111 (BARC) is applied onto a to-be-processed film 110, such as poly-Si (polysilicon) (step S1201 of FIG. 12). As the bottom antireflection film (BARC) used here, an organic BARC, such as ARC29a (produced by Nissan Chemical Industries, Ltd.), of 85 nm in film thickness is used as an organic BARC.

Next, as shown in FIG. 11B, a first resist pattern 112 is formed (step 1202).

Moreover, the first resist pattern 112 is slimmed (step S1203). As shown in FIG. 11C, with the slimmed first resist pattern 112 as a mask, a first antireflection film 111 is processed (step S1204).

Thereafter, the first resist pattern 112 is insolubilized (step S1205) by the method explained in the first embodiment. Then, on the insolubilized pattern 112, a second antireflection film (BARC) 113 is formed as shown in FIG. 11D (step S1206). In the resist insolubilizing process, the first antireflection film 111 may be insolubilized at the same time.

Further on the second antireflection film 113, a second resist pattern 114 is formed as shown in FIG. 11E (step S1207). Then, as shown in FIG. 11F, with the second resist pattern 114 as a mask, the second antireflection film 113 is processed (step S1208).

Thereafter, as shown in FIG. 11F, with the first resist pattern 112 or first antireflection film 111 and the second resist pattern 114 or second antireflection film 113 as a mask, the film 110 is processed (step S1209). Finally, the resist and antireflection film are peeled (step S1210).

By doing this, it is possible to obtain a desired pattern of the to-be-processed film 110, for example, the contact fringe and gate pattern formed in the first embodiment.

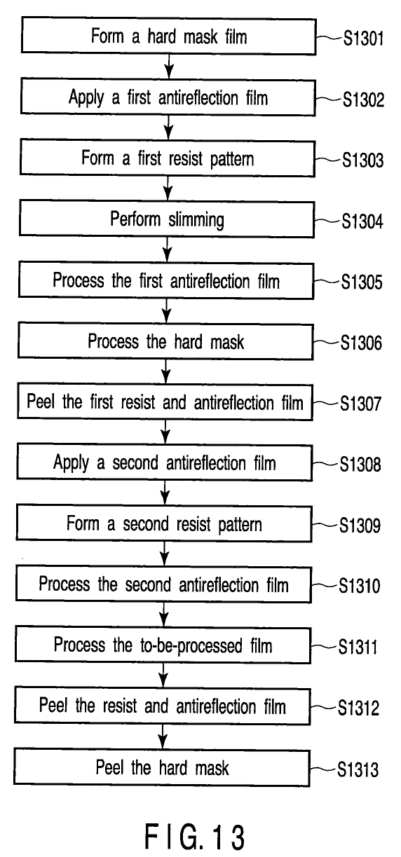

FIG. 13 is a flowchart to help explain a case where a hard mask is used.

As a result of forming an antireflection film (BARC), the processes of applying an antireflection film and etching the antireflection film are added. Moreover, not only the process of removing the resist but also the process of peeling the antireflection film is needed. However, the comparison of the flowchart of FIG. 12 of the third embodiment with that of FIG. 13 has shown that use of two layers of resist pattern decreases the number of processes by threes as compared with the case where a hard mask is used. That is, the number of processes and the cost can be reduced in forming the same pattern as when a hard mask is used.

In the third embodiment, an antireflection film (BARC) is formed twice, that is, for each of the first resist pattern 112 and second resist pattern 114. As compared with the case where a hard mask is used, the pattern forming method of laying two layers of resist one on the other enables the number of processes to decrease. However, the number of processes is still very large.

One method of decreasing the number of processes is to use BARC made soluble in a developer by exposure, which is called developer soluble BARC. Specifically, developer soluble BARC, such as AZKrFE01 (produce by AZ), NCA800 (produced by Nissan Chemical Indus tried, Ltd.), or IMBARC10-7 (produced by Brewer Science), can be used.

Use of the developer soluble BARC as an antireflection film in the third embodiment enables the antireflection film, on which the resist is soluble in developer by exposure, to dissolve in the developer and an antireflection film, on which the resist is insoluble in developer by exposure, not to dissolve in the developer at the time of developing the resist. This makes it possible to leave an antireflection film only in a place where there is a resist pattern and remove the antireflection film in a place where there is no resist pattern after forming a resist pattern, which therefore enables the processes of processing (or etching) the antireflection films in steps S1204 and S1208 of FIG. 12 to be eliminated.

### Fourth Embodiment

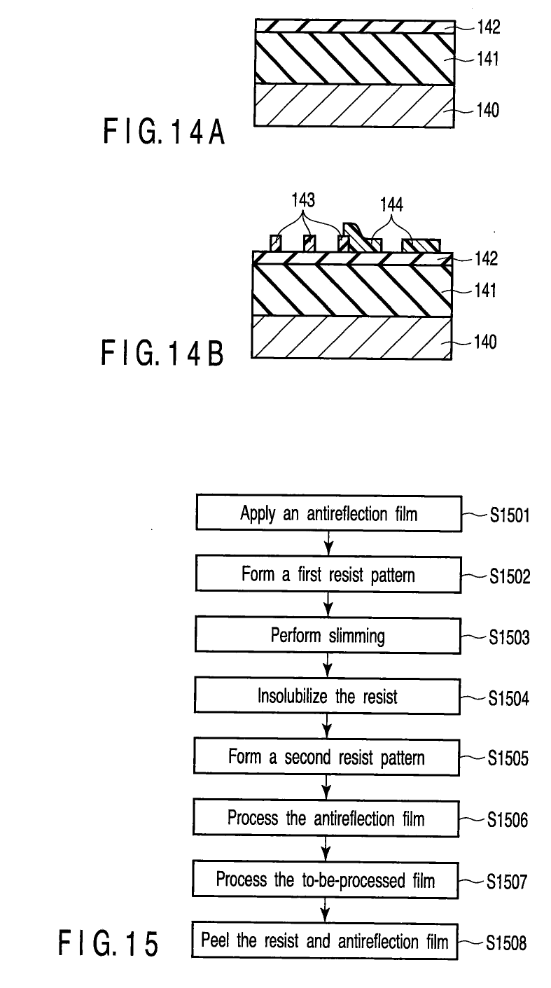

A pattern forming method according to a fourth embodiment of the invention will be explained using FIGS. 14A and 14B and FIG. 15.

In the pattern forming method of the fourth embodiment, to make the number of processes less than that in the pattern forming method of the third embodiment, the bottom anti-reflective coating (BARC) used in forming the first resist pattern is also used in forming the second resist pattern. If a variation in the optical constant of the bottom anti-reflective coating in the resist insolubilizing process is sufficiently small, can use a common bottom anti-reflective coating can be used in both the first and second resist patterning.

FIGS. 14A and 14B are sectional views to help explain the pattern forming method of the fourth embodiment. FIG. 15 is a flowchart to help explain the pattern forming method.

First, as shown in FIG. 14A, on a to-be-processed film 140, such as a poly-Si (polysilicon) film, a transmittance adjusting layer 141 and a phase adjusting layer 142 acting as a bottom antireflection film (BARC) are formed in sequence (step S1501 of FIG. 15). The transmittance adjusting layer 141, which is made of spin-on carbon, has a thickness of about 350 nm. The phase adjusting layer 142, which is made of spin-on glass, has a thickness of about 45 nm.

Using the same bottom antireflection film (BARC) in the first and the second resist patterning, a first resist pattern 143 is formed (step S1502), slimmed (step S1503), and resist-insolubilized (step S1504), and a second resist pattern 144 is formed (step S1505), thereby forming a two-layer resist pattern as shown in FIG. 14B. The resist insolubilizing process is carried out by the method explained in the first embodiment. At the same time, the anti-reflective coating (the transmittance adjusting layer 141 and phase adjusting layer 142) may be insolubilized.

Then, the antireflection film is processed in the following order (step S1506). With the first resist pattern 143 and second resist pattern 144 as a mask, the spin-on glass (phase adjusting layer) 142 is etched. Then, the spin-on carbon (transmittance adjusting layer) 141 is etched with the spin-on glass pattern 142 as a mask.

Furthermore, with the processed spin-on carbon pattern 141 as a mask, the 150-nm-thick film 140 (poly-Si) is processed (step S1507).

Finally, the resist and antireflection film are all peeled (step S1508).

By doing this, a fringed line-shaped poly-Si pattern having the desired critical dimensions as shown in FIG. 1 can be formed.

The number of processes in the above pattern forming method can be less than that in the pattern forming method of the third embodiment (see FIG. 12), which enables the cost to be decreased.

While in the fourth embodiment, the two-layer antireflection film (BARC) composed of a transmittance adjusting layer and a phase adjusting layer has been used, a single-layer organic BARC may be used as an anti-reflective coating common to the first and second resist patterns. In this case, when the film 140 is processed, the first resist pattern 143 and second resist pattern 144 generally remain. In step S1507, the first resist pattern 143, second resist pattern 144, and antireflection film serve as a mask for the to-be-processed film.

When the antireflection film is shared by the two resist patterns, regardless of whether the anti-reflective coating is composed of a single layer or two layers, this eliminates the process of processing (etching) the first antireflection film (step S1204) after sliming (step S1203) and the process of applying the second antireflection film (step S1206), which reduces the number of processes.

Furthermore, sharing the antireflection film decreases the height differences especially in a three-layer resist process where the bottom anti-reflective coating (BARC) is composed of the phase adjusting layer and transmittance adjusting layer.

When the bottom anti-reflective coating is composed of the phase adjusting layer and transmittance adjusting layer, it is desirable that both the phase adjusting layer and transmittance adjusting layer should be thin. However, since the transmittance adjusting layer acts as a mask in processing the to-be-processed film, it must be made thicker if the selectivity of the transmittance adjusting layer to the to-be-processed film is low. Accordingly, in the case where an antireflection film is provided for each resist pattern like third embodiment, it is seen from FIG. 11F that forming the second resist pattern 114 on the two-layer second antireflection film 113 makes the height difference particularly large.

However, when an antireflection film (BARC) common to the first and second resist patterns is used as in the fourth embodiment, a height difference caused by BARC does not appear as shown in FIG. 14B and therefore a large focus margin is not needed.

The above description was given, referring to the pattern of the first embodiment. However, the method of using the anti-reflective coating in common to both the first and second resist patterns is also applicable to the pattern of the second embodiment. In this case, the slimming step (S1503) is executed between the formation step (S1505) of the second resist pattern and the processing step (S1506) of the antireflection film.

In the fourth embodiment, for example, a poly-Si film has been used as a to-be-processed film serving as a gate material. However, the gate material is not limited to the poly-Si film and other material may be used.

While in the fourth embodiment, the explanation has been given on the consumption that there is no etching bias, it goes without saying that the critical dimensions of the resist may be adjusted, taking into account the etching bias according to the process.

In the first, third, and fourth embodiments, the explanation has been given using a case where a line pattern and a contact fringe pattern are formed in a gate layer composed of the to-be-processed film. However, the patterns are not restricted to these.

The fourth embodiment may be applied to a case where a micropattern which prevents a sufficient margin from being obtained by lithographic patterning and has to be formed by slimming is mixed with a narrow space pattern which cannot be formed by slimming or a pattern which prevents the necessary margin from being obtained if patterning is done in consideration of the amount of slimming.

Specifically, first, the patterns are divided into a first resist pattern and a second resist pattern in such a manner that the first resist pattern includes a micropattern which has to be formed by slimming and the second resist pattern includes a narrow space pattern which cannot be formed by slimming or a pattern which prevents the necessary margin from being obtained if patterning is done in consideration of the amount of slimming.

Next, a first pattern and a second pattern are formed separately. After the first resist pattern is formed, only the first resist pattern is slimmed. This makes it possible to select such a condition the maximum margin to be obtained for each resist pattern, which enables both the patterns to be formed with a sufficient margin. At the same time, the number of processes and the cost can be reduced as compared with the pattern forming method using a hard mask.

As described above, according to one aspect of this invention, there is provided a pattern forming method capable of reducing the number of processes and the cost in the case where there are a plurality of patterns that cannot be easily formed by single exposure, especially in the case where there are a pattern which cannot be formed without slimming and a pattern which can be formed without slimming and which cannot be formed if slimming is executed.

### Fifth Embodiment

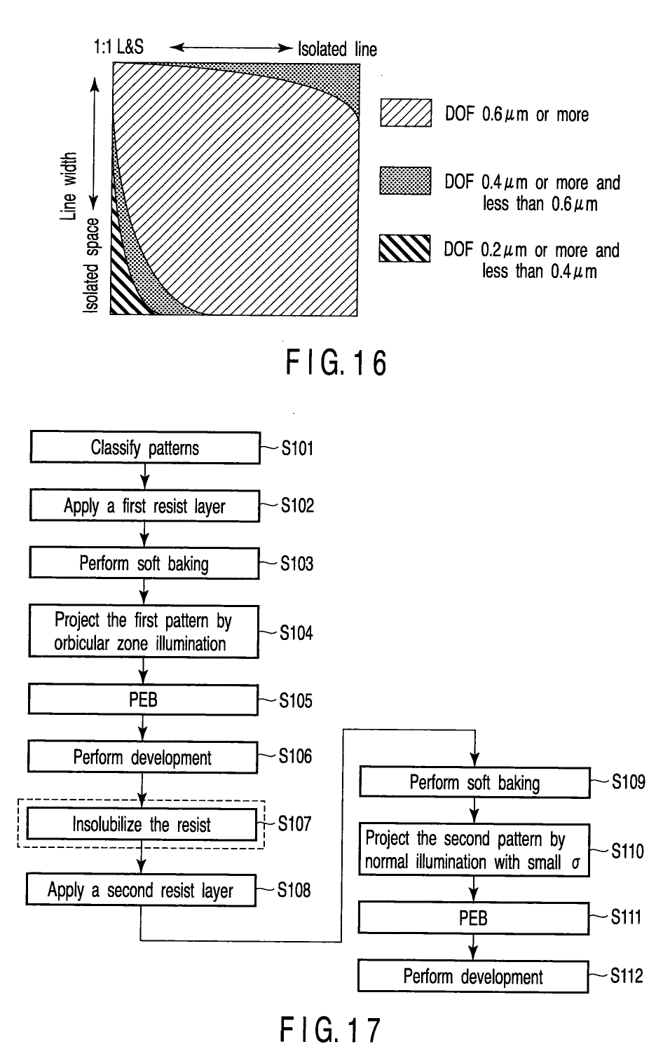

A pattern forming method according to a fifth embodiment of the invention will be explained using FIGS. 16 and 17.

In the fifth embodiment, when it is difficult to form all desired patterns with a sufficient exposure margin by single illumination, the desired patterns are divided into two groups and each of the groups is exposed by illumination of a different shape. By doing this, a pattern belonging to one group is formed on a first-layer resist and a pattern belonging to the other group is formed on a second-layer resist.

A case where it is difficult to form all patterns with a sufficient exposure margin by single illumination will be explained using FIG. 16 which shows the depth of focus (DOF) for various L&S patterns.

FIG. 16 shows the depth of focus in a contour map, while changing the line width and space width, with the illumination condition fixed to orbicular zone lamination with a shielding ratio of 1/2. The top left corresponds to an L&S pattern with a line-width-to-space-width ratio of 1:1. The space width increases as the horizontal axis is closer to the right end of the map and the line width increases as the vertical axis is closer to the bottom end. In FIG. 16, the depth of focus is shown in three stages.

When devices are produced, patterns which have various duty ratios have to be formed at the same time. However, as seen from FIG. 16, in the case of isolated lines or isolated spaces, the depth of focus decreases at the fixed line or space width. In a case as shown in FIG. 16, the focus depth of a microscopic isolated space cannot be secured.

Accordingly, when various line widths and space widths are mixed in a design pattern, restrictions are imposed on design patterns to design without using patterns difficult to produce. For example, in FIG. 16, restrictions are placed so as to design without using the parts whose DOF is 0.2 to 0.4 μm most difficult to secure. That is, restrictions are put in the design stage so as not to make microscopic isolated spaces. However, with the restrictions, a desired pattern cannot be formed, leading to an increase in the chip area.

To overcome this problem, the fifth embodiment executes a resist flow according to a flowchart as shown in FIG. 17.

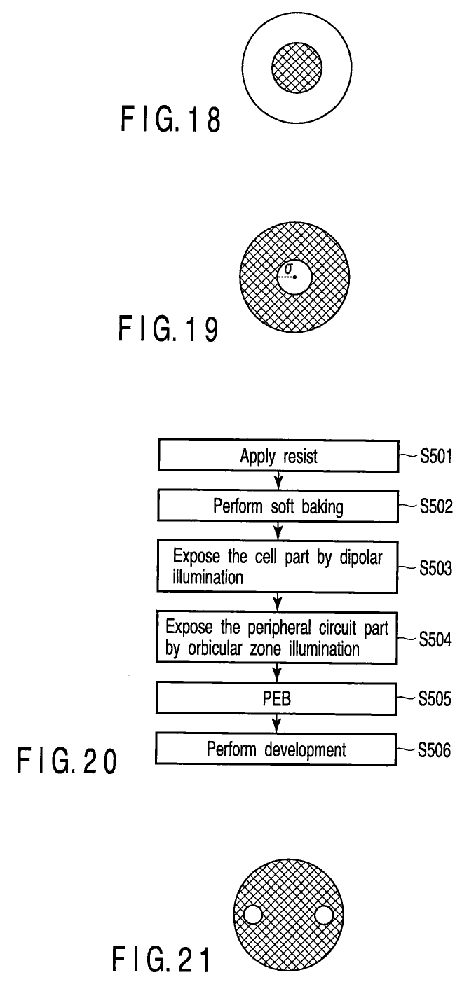

First, since a plurality of patters to be formed are divided into a first pattern group which can be formed by orbicular zone illumination (first illumination) because a depth of focus (DOF) of 0.4 μm or more can be secured by orbicular zone illumination and a second pattern group which can be formed by normal illumination with small a (second illumination) because the depth of focus (DOF) is 0.4 μm or less with orbicular zone illumination (step S101). The shape of the aperture of orbicular zone illumination and that of normal illumination with small σ are shown in FIGS. 18 and 19, respectively.

Step S101 is a step of determining a first-layer reticle pattern and a second-layer reticle pattern in forming reticles. Therefore, the step has only to be carried out once in forming reticles and need not be performed each time a pattern is formed on the wafer.

Then, a first resist layer to form a first pattern is formed (step S102). Next, soft baking is performed to volatilize the solvent of the resist (step S103).

Next, the first pattern is projected onto the first resist layer by the orbicular zone illumination serving as the first illumination (step S104). Then, post exposure baking (PEB) (step S105) and development (step S106) are performed, thereby forming a first pattern. At this time, the region for the second resist pattern is made a resist-less region in patterning the first resist layer.

Thereafter, a second resist layer is applied to form a second pattern (step S108). When the first resist pattern dissolves in applying or developing the second resist layer, the first resist pattern is insolubilized by baking, curing with UV light, DUV light, ion implantation, or the like before step S108 (step S107).

After step S108, the second resist layer is subjected to soft baking (step S109).

Next, the second pattern is projected onto the second resist layer by normal illumination with small σ, the second illumination (step S110). Moreover, post exposure baking (PEB) (step S111) and development (step S112) are performed, thereby forming a second pattern.

In the above description, reference was made to the case where the first illumination is orbicular zone illumination and the second illumination is normal illumination with small σ. However, the present invention is not limited to this combination of the types of illumination. The important point is that a pattern for which one type of illumination suitable for the other types of patterns in the same layer does not provide a sufficient depth of focus is exposed to light by performing the other type of illumination that ensures a sufficient depth of focus.

In the above description, reference was made to the case where a sufficient depth of focus cannot be provided. However, the prerequisite may be an exposure latitude or a process margin instead of depth of focus.

As described above, with the pattern forming method of the fifth embodiment, all desired patterns can be formed without putting restrictions on the design, which enables an increase in the chip area to be suppressed.

### Sixth Embodiment

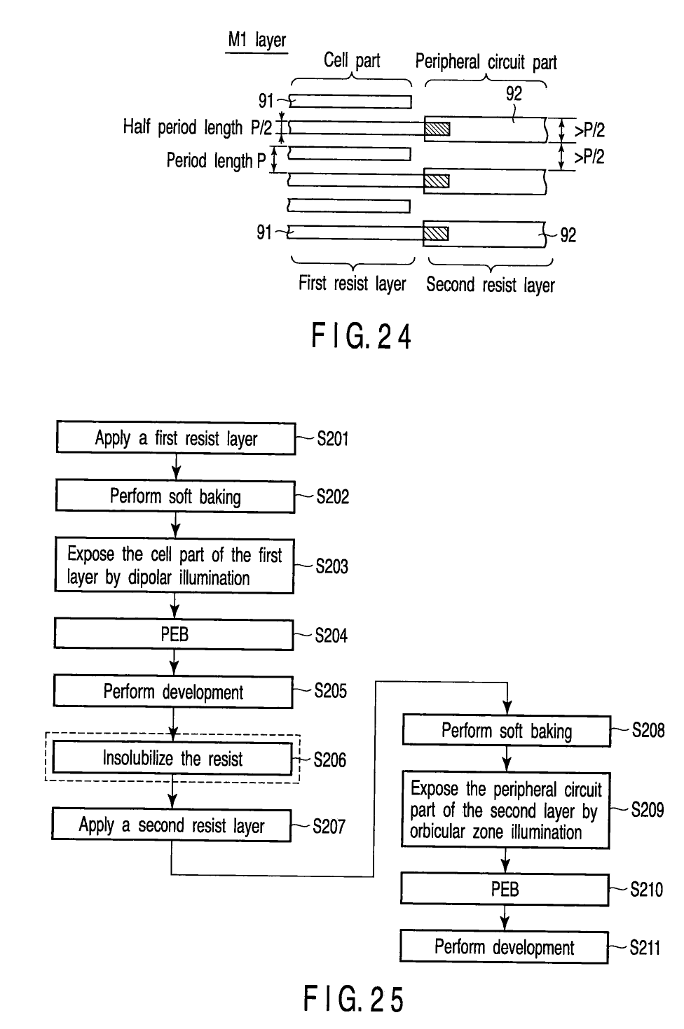

A pattern forming method according to a sixth embodiment of the invention will be explained using FIGS. 24 to 32.

In the sixth embodiment, restrictions on the patterns and the necessity of wiring in different layers encountered when a pattern is divided and each of the resulting patterns is exposed by different illumination are solved by using two layers of resist and exposing each of the layers under the optimum condition.

A case where a pattern is divided and subjected to double exposure will be explained taking the M1 layer of a NAND flash memory as an example. In the M1 layer of a NAND flash memory, since one type of microscopic periodic L&S pattern is provided in the cell part, exposure is made with the L&S mask by dipolar illumination according to the pitch of the L&S pattern.

However, although dipolar illumination improves the resolution of a unidirectional 1:1 L&S pattern with a determined pitch, an L&S pattern perpendicular to the 1:1 L&S pattern or a pattern with a different pitch is not resolved. Accordingly, the peripheral part including various L&S patterns cannot be formed by dipolar illumination and therefore be exposed by orbicular zone illumination instead of dipolar illumination.

FIG. 20 is a flowchart to help explain the process flow in this case.

After resist application (step S501) and soft baking (step S502), first, an L&S pattern is formed in the cell part by dipolar illumination (step S503). The shape of apertures of dipolar illumination is shown in FIG. 21.

Next, the peripheral circuit part is exposed by orbicular zone illumination (step S504). Then, post exposure baking (PEB) is performed (step S505). Finally, the baked part is developed (step S506), thereby producing a resist pattern of the M1 layer.

However, as described above, the patterns obtained by two exposures cannot be mixed. The reason is that, if they are mixed, the aerial images are added in the resist, which makes it impossible to get a desired performance. To avoid this problem, the place where a pattern is to be formed is divided. However, just dividing the place leads to a decrease in the contrast and the deterioration of optical images because a flare appears twice as a result of two exposures, which becomes a serious problem in narrow margin lithography.

To avoid these problems, for example, when an attempt is made to avoid the influence of flare, a shading film is provided on the reticle to shield the flare.

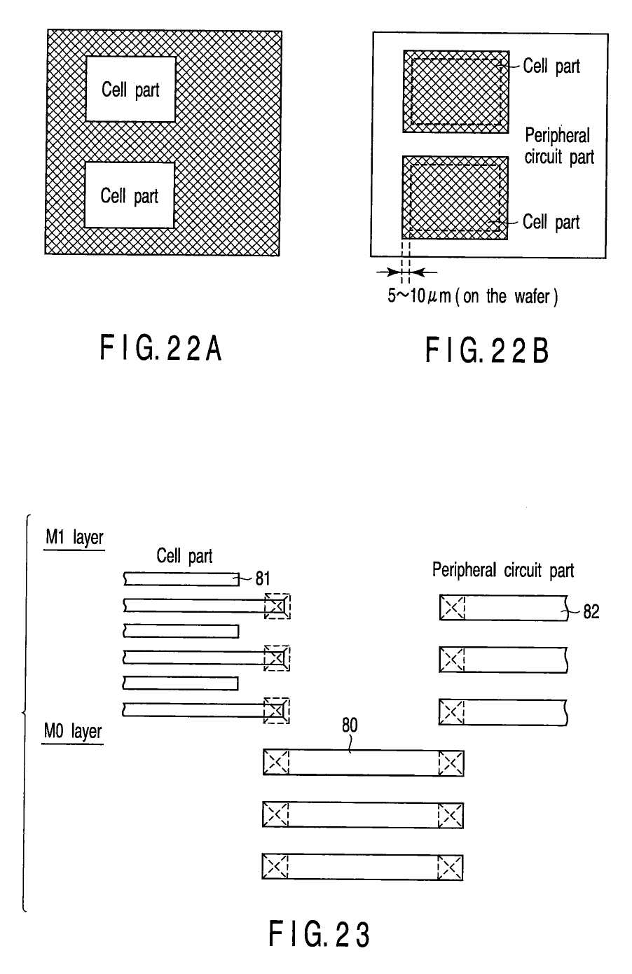

When the cell part is separated from the peripheral circuit part, reticles obtained by separating the individual patterns are prepared as shown in FIGS. 22A and 22B. In the case of a reticle of FIG. 22A used in exposing the L&S pattern of the cell part, the part corresponding to the peripheral circuit part is covered with a shading film. In the case of a reticle of FIG. 22B used in exposing the peripheral circuit part, a shading film is formed in the place corresponding to the L&S pattern. Since light goes around at the boundary between the cell part and peripheral circuit part, a pattern-less region of 20 μm to 40 μm in width is provided on the reticle. Consequently, the chip area increases.

In this case, the cell part and peripheral circuit part cannot be connected in the M1 layer. FIG. 23 shows a design pattern when the wiring lines are drawn from the cell part 81 to the peripheral circuit part 82. To draw the wiring lines from the cell part 81 to the peripheral circuit part 82, the wiring lines are drawn down from each of the cell part 81 and peripheral circuit part 82 in the M1 layer to the M0 layer, a lower layer, via contacts. In the M0 layer, the cell part 81 and peripheral part 82 are connected via wiring lines 80. Consequently, the resistance value of the wiring lines increases, the reliability decreases, and the chip area increases.

As described above, when the cell part and peripheral circuit part are exposed separately, the region is divided as shown in FIGS. 22A and 22B and a region that prevents light from going around should be formed. Moreover, as shown in FIG. 23, a contact hole down to the M0 layer is formed to connect the cell part and peripheral circuit part.

However, the formation of the region that prevents light from going around and the region to form the contact holes leads to an increase in the chip area. Moreover, the connection between the patterns in different layers results in an increase in the resistance value or a decrease in the reliability.

Accordingly, in the sixth embodiment, the cell part and peripheral circuit part are composed of different resist layers. Then, each of the cell part and peripheral part is exposed by different illumination, thereby not only securing the lithographic performance but also forming the lead lines at the same time.

FIG. 24 shows a design pattern of an extraction part which connects the cell part 91 and the peripheral circuit part 92 in the sixth embodiment. After the cell part 91 is made of a first resist layer, the peripheral circuit part 92 is made of a second resist layer on the cell part 91. As shown in FIG. 24, the second-layer resist pattern is laid on the first-layer resist pattern so as to cover a part of the first-layer resist pattern, thereby connecting the two patterns.

In FIG. 24, suppose that the period of the line and space pattern of the cell part 91 is p, the half period p/2 corresponds to the line width in the cell part. The line width and the space width of the peripheral circuit part 92 are larger than the half period length p/2.

As compared with FIG. 23, the chip area can be made small, since a contact hole need not be formed or a pattern need not be connected through the M0 layer. Moreover, the layers need not be connected using a contact hole, which helps decrease the resistance and increase the reliability.

FIG. 25 is a flowchart to help explain the pattern forming method according to the sixth embodiment. The cell part 91 is made of the first-layer resist using dipolar illumination (step S203) and only the peripheral circuit part 92 is made of the second-layer resist by orbicular zone illumination (step S209). As in the fifth embodiment, the insolubilization of the first-layer resist pattern (step S206) is needed when the first-layer resist pattern dissolves when the second-layer resist is applied.

While in the sixth embodiment, the cell part 91 is formed first, the peripheral circuit part 92 may be formed first.

In the sixth embodiment, the cell part has been formed by dipolar illumination and the peripheral circuit part has been formed by orbicular zone illumination. However, the illumination is not limited to this. The type of illumination is determined, depending on what pattern is included in the peripheral circuit part. Hereinafter, how the type of illumination is determined will be explained.

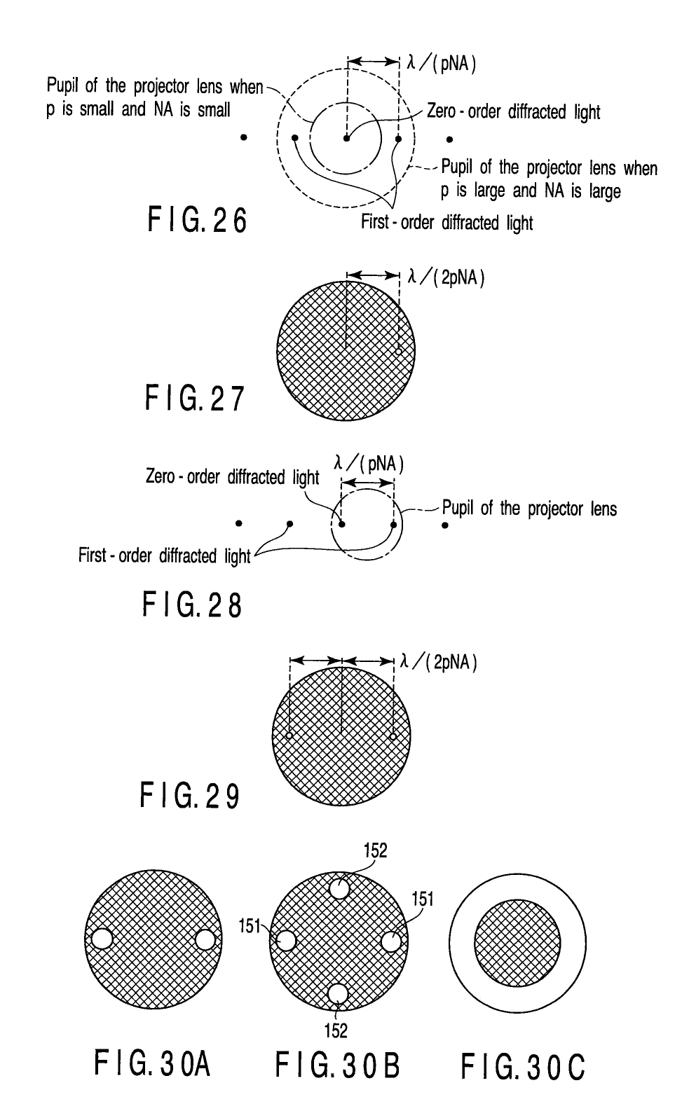

FIG. 26 shows the position of diffracted light produced by a periodic L&S pattern at the pupil of a projector lens. Diffracted light is produced in such a manner that zero-order diffracted light is produced in the center and first-order diffracted light is produced outside the zero-order diffracted light. After a plurality of the diffracted light beams pass through projector lenses, they interfere with one another on the wafer, producing a high-contrast L&S aerial image.

If the exposure wavelength is λ, the period of the L&S pattern is p, the numerical aperture of the projector lens is NA, and the radius of the pupil of the projector lens is 1, the spacing between diffracted lights is λ/(p×NA). In FIG. 26, the spacing of the diffracted lights is fixed and a change in a relative size of the pupil of the projector lens is shown with respect to the fixed spacing.

When the period p of the L&S pattern is large or the NA is large, the region indicated by a dotted line in FIG. 26 is the pupil of the projector lens, and the zero-order and first-aerial diffracted lights pass through the pupil of the projector lens, interfering with one another, which produces a high-contrast L&S aerial image. However, if p becomes smaller or the NA becomes smaller, only the zero-order diffracted light passes through the pupil of the projector lens as shown by a one-dot-dash line of FIG. 26. This prevents interference from occurring, which makes it impossible to obtain an aerial image of the resist which can be resolved.

It is oblique incidence illumination that solves the problem. For example, illumination with an opening only in the position λ/(2p×NA) from the center of the illumination as shown in FIG. 27 is used. Then, the position of the diffracted light shifts and either the zero-order or first-order diffracted light passes through the pupil of the projector lens as shown in FIG. 28, interfering with one another, which produces a high-contrast L&S aerial image. Actually, when the symmetry of the light is needed, openings are made in two positions symmetric with respect to the center of the illumination as shown in FIG. 29. This is dipolar illumination.

While the shape of illumination has been explained when viewed from the wafer side, the shape of illumination will be described as follows when viewed from the reticle side.

In oblique incidence illumination, the light that has passed through the opening illuminates the reticle obliquely. If the magnification of the reticle is M, the L&S pattern with a period of p on the wafer has a period of p×M on the reticle. For example, the M of a tetraploid reticle is 4. If the incidence angle of obliquely incident light is 0 and the exposure wavelength is λ, the incidence angle θ has to satisfy sin θ=λ/(2×p×M) to cause diffracted light beams to interfere with one another on the wafer. For diffracted light to pass through the pupil of the projector lens as shown in FIG. 28, the incidence plane of the reticle which the obliquely incident light passed through the aperture enters has to be perpendicular to the direction of the line of the L&S pattern of the reticle. Moreover, since symmetry is needed, openings have to be made in symmetric positions as shown in FIG. 29. This produces dipolar illumination.

In micropatterns, when the aperture diameter of dipolar illumination becomes too large, the background rises, preventing an image from being resolved. Therefore, dipolar illumination is used for microscopic patterns. However, when the pattern dimensions become large, an image is resolved even if the background rises because the contrast of the aerial image is high. Accordingly, as shown in FIG. 30A, the aperture diameter of dipolar illumination can be made larger.

Furthermore, even if L&S patterns with different period is present, they can be resolved if the diffracted light beams have only to arrive, except for the end of the periodic pattern. Moreover, when the pattern becomes larger, the image is resolved even by quadrupolar illumination (FIG. 30B) or orbicular zone illumination (FIG. 30C). In this case, not only diffracted light from a vertical line but also diffracted light from a horizontal line pass through the pupil of the projector lens, which causes both the vertical line and horizontal line to be resolved by single exposure.

Although quadrupolar illumination is excellent in resolution because the background is suppressed, the amount of light decreases. When an oblique line is present, the image is not resolved by quadrupolar illumination and orbicular zone illumination has to be used.

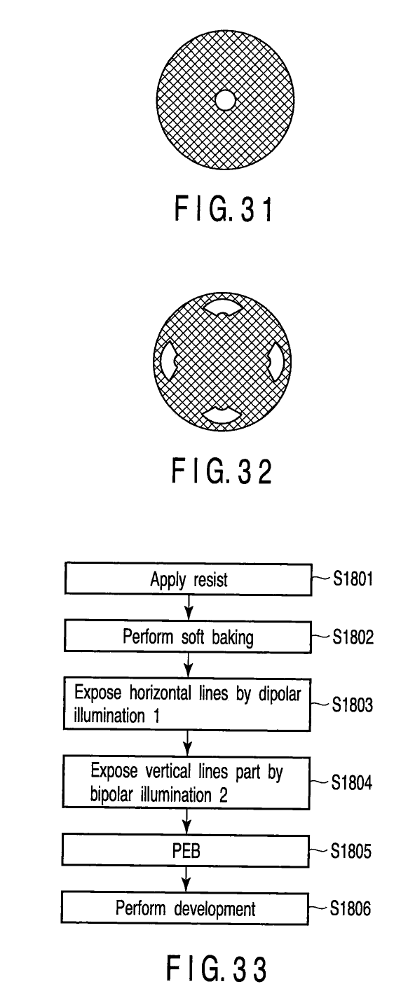

The periodic pattern has been described above. In the case of an isolated pattern, zero-order light contributes mainly to image formation and therefore the interference effect cannot be expected. That is the reason why an isolated pattern makes only a large pattern. When only isolated patterns are formed, it is desirable that normal illumination with small σ as shown in FIG. 31 should be used to prevent zero-order light from arriving and the background from rising.

What has been explained above is summarized as follows. In the cell part composed of periodic patterns, if the pattern dimensions are close to the resolution limit, dipolar illumination is used. If the pattern dimensions are larger than the resolution limit, quadrupolar illumination is used. If the pattern dimensions are much larger, orbicular zone illumination may also be used. However, if not only a straight pattern but also an oblique pattern are included, quadrupolar illumination cannot be used and orbicular zone illumination has to be used.

Since the pattern dimensions of the peripheral circuit part are larger than those of the cell part, there is room for the resolution limit. In addition, patterns with different periods exist in both the horizontal and vertical directions. When the peripheral circuit part includes an isolated pattern, at least an opening has to be in the center of the illumination. For this reason, normal illumination is often used. When the peripheral circuit part includes no insolated pattern, an opening need not be made in the center of the illumination and orbicular illumination or quadrupolar illumination is used.

As described above, illumination varies according to the type of pattern and the pattern dimensions. Since illumination further depends on the performance of resist and the exposure condition, including flare, it has to be selected suitably.

In the sixth embodiment, the relationship between the pattern and the normally used illumination shape has been explained qualitatively. For the sake of more accurate explanation, the aerial images of the included patterns may be calculated using candidate illumination shapes and the illumination shape which maximizes a process window, including the optimization of the mask dimensions, may be selected.

Moreover, the illumination shape may not be restricted to dipolar illumination or quadrupolar illumination. Customized illumination whose shape maximizing the process window of the included patterns may be used.

While in the sixth embodiment, the explanation has been given on the assumption that the aperture of dipolar illumination or quadrupolar illumination is circular, the aperture is not restricted to a circle and may be of a fan shape as shown in FIG. 32, since diffracted light has only to enter the aperture. Moreover, it is necessary that illumination should have apertures in which diffracted light beams necessary for interference go through. For example, dipolar illumination with an opening in its center may be used.

Furthermore, not only is an illumination shape produced by making an opening, but also a similar illumination shape may be produced by making the luminance high or low using the diffraction of light or the like, which is a known method (e.g., A. Engelen, et at., “Implementation of Pattern Specific Illumination Pupil Optimization on Step & Scan System,” Proc. of SPIE, vol. 5377, pp. 1323 (2004)). In this case, the light intensity in the place corresponding to the aperture is higher than its surrounding.

The aforementioned illumination selecting method is also applicable to a contact hole pattern. The difference between the L&S pattern and the contact hole pattern is such that diffracted light beams line up one-dimensionally because the L&S pattern is a one-dimensional pattern and diffracted light beams appear in a reticular pattern because the contact hole pattern is a two-dimensional pattern. The remaining part of the illumination selecting method in the contact hole pattern is the same as that in the L&S pattern. Therefore, the above-described illumination selecting method can be applied.

Specifically, for example, a pattern made of the first resist layer is a contact hole pattern with both a horizontal and a vertical period length of p as shown in FIG. 37.

First illumination which exposes the contact hole pattern is quadrupolar illumination as shown in FIG. 30B. If the radius of illumination is 1 and the numerical aperture of the projector lens is NA, an opening is made in the position the exposure wavelength/(2p×NA) from the center of illumination. The direction in which two openings 151 are connected in FIG. 30B is perpendicular to the direction in which the contact hole patterns line up vertically in FIG. 37. That is, the exposure light passing through the two openings 151 resolves the edges 221, 222, 223, 224 of the contact hole pattern of FIG. 37. The remaining edges perpendicular to these are resolved by the two openings 152 in FIG. 30B.

Then, for example, a pattern made of the second resist layer whose period is larger than the period p of the contact hole pattern made of the first resist layer is formed by quadrupolar illumination differing from the one described above.

Furthermore, the illumination selecting method described above is also applicable to a case similar to the sixth embodiment.

### Seventh Embodiment

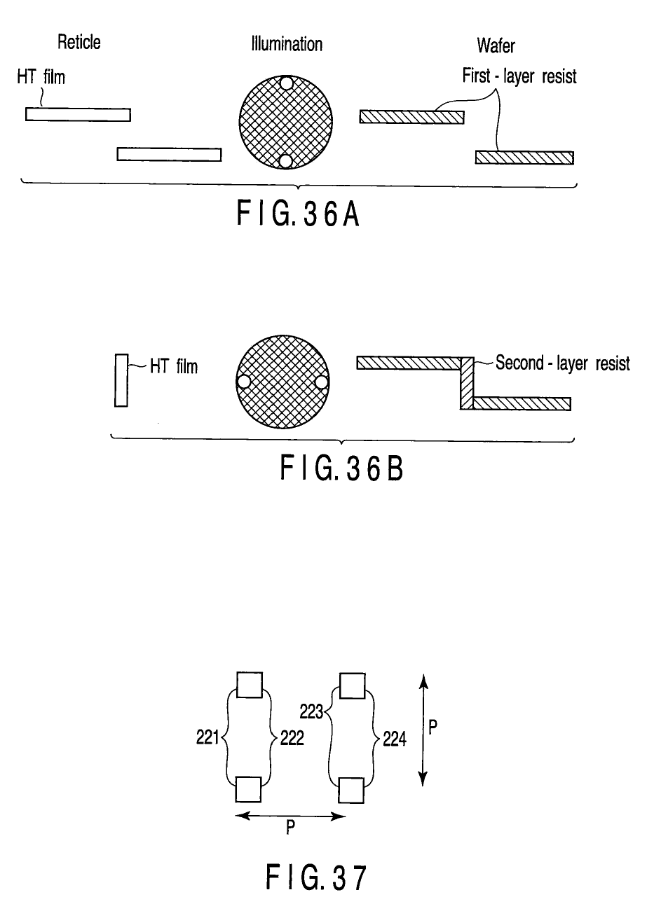

A pattern forming method according to a seventh embodiment of the invention will be explained using FIGS. 35, 36A, and 36B.

In the seventh embodiment, an explanation will be given about a method of forming microscopic wiring lines by laying two layers of resist one on the other with dipolar illumination.

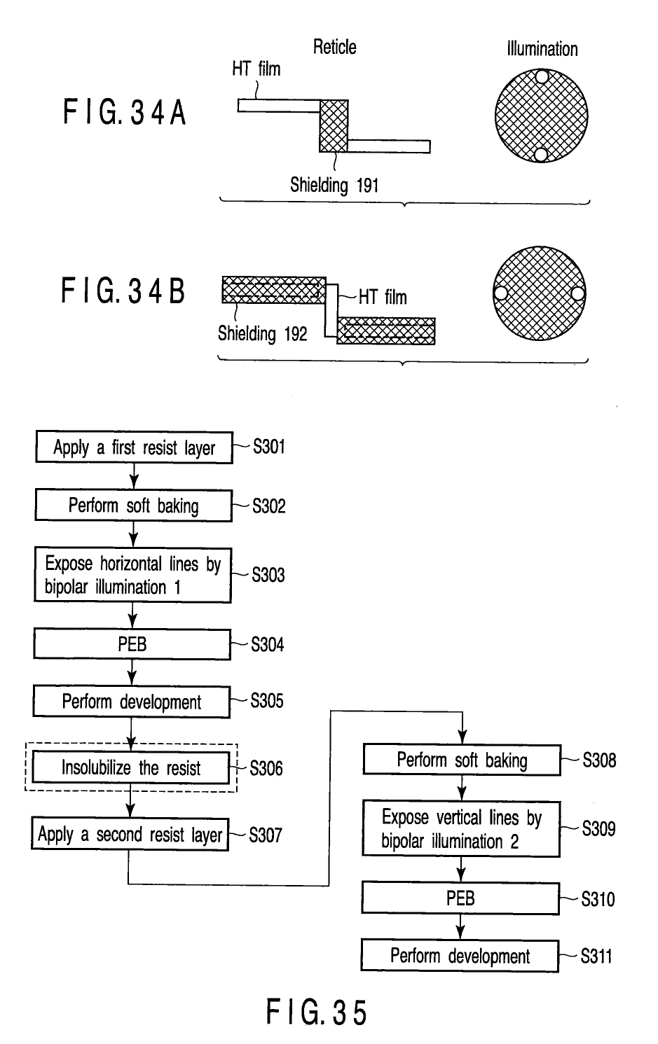

DDL has been proposed which applies one layer of resist and then forms vertical lines and horizontal lines by two types of dipolar illumination. As shown in the flowchart of FIG. 33 and in FIGS. 34A and 34B, the process flow of DDL advances in this order: the application of resist (step S1801 of FIG. 33), soft baking (step S1802), the exposure of horizontal lines (first dipolar illumination) (step S1803 of FIG. 34A), the exposure of vertical lines (second dipolar illumination) (step S1804 of FIG. 34B), PEB (step S1805), and development (step S1806). (FIGS. 34A and 34B show only one period of a periodic reticle pattern.)

As described above, in a region to be exposed by the other exposure, shielding patterns 191, 192 larger than the pattern have to be placed as shown in FIGS. 34A and 34B, which leads to an increase in the chip area. Furthermore, to connect the vertical and horizontal lines, it is necessary to connect them at a tricky shielding part 191 where the contrast of the aerial images is low as shown in FIGS. 34A and 34B, which decreases the reliability of the wiring.

To overcome this problem, in the seventh embodiment, the vertical lines and horizontal lines made of different resist layers are formed. This process is shown in the flowchart of FIG. 35. FIGS. 36A and 36B show the states of the reticle, illumination, and wafer. In FIGS. 36A and 36B, only one period of the periodic reticle pattern is shown.

After one layer of resist is applied (step S301 of FIG. 35) and soft baking is done (step S302), the horizontal L&S pattern is exposed by dipolar illumination (step S303). In this case, dipolar illumination as shown in FIG. 36A is used.

Thereafter, PEB (step 304) and development (step S305) are performed, thereby forming a first-layer resist pattern. If the first-layer resist pattern dissolves at the time of the application or patterning of a second-layer resist, the first-layer resist pattern is insolubilized before the application of a second-layer resist as in the fifth and sixth embodiments (step S306).

Next, a second-layer resist is applied (step S307) and soft baking is performed (step S308). Thereafter, the vertical L&S pattern is exposed (step S309) using dipolar illumination whose apertures are shifted 90 degrees from that of the illumination used for the exposure of the first layer (step S309). Then, PEB (step 310) and development (step S311) are performed, thereby forming a second-layer resist pattern.

Generally, in the case of the L&S pattern whose period of the horizontal line is p₁, diffracted light has to pass through the pupil of the projector lens as described in the second embodiment. Accordingly, if the radius of illumination is 1 and the numerical aperture of the projector lens is NA₁, dipolar illumination of FIG. 36A is such that openings are made in two positions which are opposite each other with respect to the center of illumination and which are the exposure wavelength/(2p₁×NA₁) away from the center of illumination in a direction perpendicular to the horizontal line of the L&S pattern. Alternatively, illumination shape may be formed using the diffraction of light or the like instead of using an aperture so that the light intensity becomes higher in the two positions than that in their surrounding.

Similarly, in the case of the L&S pattern whose period of the vertical line is p₂, if the radius of illumination is 1 and the numerical aperture of the projector lens is NA₂, dipolar illumination of FIG. 36B is such that openings are made in two positions which are opposite each other with respect to the center of illumination and which are the exposure wavelength/(2p₂×NA₂) away from the center of illumination in a direction perpendicular to the vertical line of the L&S pattern. Alternatively, illumination shape may be formed using the diffraction of light or the like instead of using an aperture so that the light intensity becomes higher in the two positions than that in their surrounding.

In this method, the first-layer and second-layer resist patterns are formed separately, preventing the effect of a flare and the aerial images from being added in the resist, which leads to better lithographic performance than that in double exposure with single layer resist. Moreover, instead of connecting the vertical line with the horizontal line on the basis of a low-contrast aerial image formed by the shading film, the vertical line can be laid on the horizontal line and connected on the basis of a high-contrast aerial image, which improves the reliability of the wiring.

Furthermore, when a plurality of periodic L&S patterns each of which has a period of pᵢ (i=1, 2, 3, . . . ) and which are parallel with one another are resolved, diffracted light has to pass through the pupil of the projector lens as described above. Specifically, if the radius of illumination is 1 and the numerical aperture of the projector lens is NA, the aperture of dipolar illumination used for a plurality of period pᵢ (i=1, 2, 3, . . . ) of the L&S pattern is such that openings are made in two positions which are opposite each other with respect to the center of illumination and which contains the position that are λ/(2pᵢ×NA) away from the center of illumination in a direction perpendicular to the line of the L&S pattern. Alternatively, illumination shape may be formed using the diffraction of light or the like instead of an aperture, so that the light intensity becomes higher at the two openings than that in their surrounding.

This holds true for both the horizontal lines and vertical lines. Therefore, when there are a plurality of periodic L&S patterns parallel with one another in the horizontal direction and a plurality of periodic L&S patterns parallel with one another in the vertical direction, two types of illumination as described above are prepared according to the horizontal and vertical L&S patterns. Then, use of the two types of illumination is switched between the two resist layers.

As described above, in the seventh embodiment, when a plurality of types of patterns are formed, the patterns are divided into the patterns which can be formed by a first illumination shape and the patterns which can be formed by a second illumination shape different from the first one. The patterns formable by the first illumination are made of a first resist layer. The patterns formable by the second illumination are made of a second resist layer different from the first one.

This makes it possible to expose and develop each of the resist layers under the optimum conditions and perform patterning so as to achieve the maximum contrast, which enables a wide exposure margin to be obtained. That is, it is possible to obtain the maximum lithographic performance and a wide process margin.

Furthermore, since two resist layers can be laid one on the other, there is no pattern restriction and therefore the chip area can be reduced. Moreover, a tricky pattern need not be used, which improves the reliability of the wiring.

As described above, according to an aspect of the invention, it is possible to provide a pattern forming method capable of easing pattern restrictions, reducing the chip area, and improving the reliability of the wiring.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A pattern forming method comprising:
forming a first resist pattern on a to-be-processed film;
slimming the first resist pattern;
forming a second resist pattern on at least either the slimmed first resist pattern or the to-be-processed film; and
processing the to-be-processed film, with the first and second resist patterns as a mask.

2. The pattern forming method according to claim 1, wherein the first resist pattern includes a micropattern which needs slimming, and
the second resist pattern includes a pattern incapable of being slimmed together with the first resist pattern.

3. The pattern forming method according to claim 1, further comprising: insolubilizing the first resist pattern after slimming the first resist pattern and before forming the second resist pattern.

4. The pattern forming method according to claim 1, further comprising: dividing a plurality of types of patterns to be formed on the to-be-processed film into a first pattern formed by first illumination in a first illumination shape and a second pattern formed by second illumination in a second illumination shape differing from the first illumination shape,
wherein forming the first resist pattern includes projecting the first pattern onto a first resist layer by the first illumination and developing the first resist layer, and
forming the second resist pattern includes projecting the second pattern onto a second resist layer by the second illumination and developing the second resist layer.

5. The pattern forming method according to claim 4, wherein the first pattern is a periodic pattern where the same patterns line up, and
the second pattern is a peripheral circuit pattern including a plurality of types of patterns.

6. The pattern forming method according to claim 4, wherein the first pattern is a line and space pattern whose period is p,
the first illumination is dipolar illumination and is provided with an opening part or a region higher in light intensity than its surrounding so as to include two positions separated from a center of the illumination by the exposure wavelength/(2p×NA) on the consumption that the radius of illumination is 1 and the numerical aperture of a projector lens is NA, the line connecting the two positions crossing at right angles with the direction of the line of the first pattern, and
the second pattern is a pattern whose line width and space width are both larger than p/2.

7. The pattern forming method according to claim 4, wherein the first pattern is a line and space pattern whose period is P₁,
the first illumination is dipolar illumination and is provided with an opening part or a region higher in light intensity than its surrounding so as to include two positions separated from a center of the illumination by the exposure wavelength/(2p₁×NA₁) on the consumption that the radius of illumination is 1 and the numerical aperture of a projector lens is NA₁, the line connecting the two positions crossing at right angles with the direction of the line of the first pattern,
the second pattern is a line and space pattern whose period is P₂ crossing at right angles with the line and space pattern of the first pattern, and
the second illumination is dipolar illumination and is provided with an opening part or a region higher in light intensity than its surrounding so as to include two positions separated from a center of the illumination by the exposure wavelength/(2p₂×NA₂) on the consumption that the radius of illumination is 1 and the numerical aperture of a projector lens is NA₂, the line connecting the two positions crossing at right angles with the direction of the line of the second pattern.

8. A pattern forming method comprising:
forming a first bottom anti-reflective coating on a to-be-processed film;
forming a first resist pattern on the first bottom anti-reflective coating;
slimming the first resist pattern;
processing the first bottom anti-reflective coating with the slimmed first resist pattern as a mask;
forming a second bottom anti-reflective coating on the first resist pattern and the to-be-processed film, after processing the first bottom anti-reflective coating;
forming a second resist pattern on the second bottom anti-reflective coating;
processing the second bottom anti-reflective coating with the second resist pattern as a mask; and
processing the to-be-processed film, with the first resist pattern or the first bottom anti-reflective coating pattern, and the second resist pattern or the processed second bottom anti-reflective coating pattern as a mask.

9. The pattern forming method according to claim 8, wherein the first resist pattern includes a micropattern which needs slimming, and
the second resist pattern includes a pattern incapable of being slimmed together with the first resist pattern.

10. The pattern forming method according to claim 8, further comprising: insolubilizing the first resist pattern after processing the first bottom anti-reflective coating and before forming the second bottom anti-reflective coating.

11. The pattern forming method according to claim 8, further comprising: dividing a plurality of types of patterns to be formed on the to-be-processed film into a first pattern formed by first illumination in a first illumination shape and a second pattern formed by second illumination in a second illumination shape differing from the first illumination shape,
wherein forming the first resist pattern includes projecting the first pattern onto a first resist layer by the first illumination and developing the first resist layer, and
forming the second pattern includes projecting the second resist pattern onto a second resist layer by the second illumination and developing the second resist layer.

12. The pattern forming method according to claim 11, wherein the first pattern is a periodic pattern where the same patterns line up, and
the second pattern is a peripheral circuit pattern including a plurality of types of patterns.

13. The pattern forming method according to claim 11, wherein the first pattern is a line and space pattern whose period is p,
the first illumination is dipolar illumination and is provided with an opening part or a region higher in light intensity than its surrounding so as to include two positions separated from a center of the illumination by the exposure wavelength/(2p×NA) on the consumption that the radius of illumination is 1 and the numerical aperture of a projector lens is NA, the line connecting the two positions crossing at right angles with the direction of the line of the first pattern, and
the second pattern is a pattern whose line width and space width are both larger than p/2.

14. The pattern forming method according to claim 11, wherein the first pattern is a line and space pattern whose period is P₁,
the first illumination is dipolar illumination and is provided with an opening part or a region higher in light intensity than its surrounding so as to include two positions separated from a center of the illumination by the exposure wavelength/(2p₁×NA₁) on the consumption that the radius of illumination is 1 and the numerical aperture of a projector lens is NA₁, the line connecting the two positions crossing at right angles with the direction of the line of the first pattern,
the second pattern is a line and space pattern whose period is P₂ crossing at right angles with the line and space pattern of the first pattern, and
the second illumination is dipolar illumination and is provided with an opening part or a region higher in light intensity than its surrounding so as to include two positions separated from a center of the illumination by the exposure wavelength/(2p₂×NA₂) on the consumption that the radius of illumination is 1 and the numerical aperture of a projector lens is NA₂, the line connecting the two positions crossing at right angles with the direction of the line of the second pattern.

15. A pattern forming method comprising:
forming a bottom anti-reflective coating on a to-be-processed film;
forming a first resist pattern on the bottom anti-reflective coating;
slimming the first resist pattern;
forming a second resist pattern on at least either the bottom anti-reflective coating or the slimmed first resist pattern;
processing the bottom anti-reflective coating, with the first and second resist patterns as a mask; and
processing the to-be-processed film, with the first resist pattern, second resist pattern, or the processed bottom anti-reflective coating as a mask.

16. The pattern forming method according to claim 15, wherein the first resist pattern includes a micropattern which needs slimming, and
the second resist pattern includes a pattern incapable of being slimmed together with the first resist pattern.

17. The pattern forming method according to claim 15, further comprising: insolubilizing the first resist pattern after slimming the first resist pattern and before forming the second resist pattern.

18. The pattern forming method according to claim 15, further comprising: dividing a plurality of types of patterns to be formed on the to-be-processed film into a first pattern formed by first illumination in a first illumination shape and a second pattern formed by second illumination in a second illumination shape differing from the first illumination shape,
wherein forming the first resist pattern includes projecting the first pattern onto a first resist layer by the first illumination and developing the first resist layer, and
forming the second resist pattern includes projecting the second pattern onto a second resist layer by the second illumination and developing the second resist layer.

19. The pattern forming method according to claim 18, wherein the first pattern is a periodic pattern where the same patterns line up, and
the second pattern is a peripheral circuit pattern including a plurality of types of patterns.

20. The pattern forming method according to claim 18, wherein the first pattern is a line and space pattern whose period is p,
the first illumination is dipolar illumination and is provided with an opening part or a region higher in light intensity than its surrounding so as to include two positions separated from a center of the illumination by the exposure wavelength/(2p×NA) on the consumption that the radius of illumination is 1 and the numerical aperture of a projector lens is NA, the line connecting the two positions crossing at right angles with the direction of the line of the first pattern, and
the second pattern is a pattern whose line width and space width are both larger than p/2.
